(19) United States
(12) Patent Application Publication
(10) Pub. No.: US 2021/0320233 A1
(43) Pub. Date: Oct. 14, 2021

(54) LIGHT-EMITTING DEVICE AND ILLUMINATING APPARATUS COMPRISING THE SAME

(71) Applicant: Xiamen Sanan Optoelectronics Technology Co., LTD, Xiamen (CN)

(72) Inventors: Hailin Rao, Xiamen (CN); Shaohua Huang, Xiamen (CN); Xiaoqiang Zeng, Xiamen (CN); Lixun Yang, Xiamen (CN); Shuiqing LI, Xiamen (CN); Linrong CAI, Xiamen (CN)

(21) Appl. No.: 17/356,755

(22) Filed: Jun. 24, 2021

Related U.S. Application Data
(63) Continuation-in-part of application No. PCT/CN2020/070087, filed on Jan. 2, 2020.

(51) Int. Cl. H01L 33/58; H01L 33/48; H01L 33/50; H01L 33/60; H01L 33/62

(52) U.S. Cl. CPC H01L 33/58; H01L 33/486; H01L 33/62; H01L 33/60; H01L 33/50

(57) ABSTRACT

A light-emitting device includes an LED chip disposed on a supporting component. The LED chip includes a semiconductor stack formed on a substrate, a first electrode, and a second electrode. A light-blocking layer fills the supporting component to cover a lateral side of the LED chip and expose a top chip surface of the LED chip. The light-blocking layer has a top surface not lower than the top chip surface of the LED chip. A height difference among the top chip surface, the top surface of the light-blocking layer and a top end of the supporting component is less than 10 μm. A top light exit port defined by the light-blocking layer to expose the top chip surface has a cross sectional area not larger than that of the top chip surface.

### CROSS-REFERENCE TO RELATED APPLICATION

This application is a bypass continuation-in-part (CIP) application of PCT International Application No. PCT/CN2020/070087, filed on Jan. 2, 2020. The entire content of the international patent application is incorporated herein by reference.

### FIELD

The disclosure relates to a light-emitting device and an illuminating apparatus comprising the same, and more particularly to a light-emitting device with a limited light-emitting surface and an illuminating apparatus comprising the same.

### BACKGROUND

Light-emitting diodes (LEDs) are profusely employed as a solid-state light source. Compared with conventional incandescent bulbs and fluorescent lamps, LEDs have advantages of low power consumption and long service life. As LED technology matures, LEDs have gradually replaced conventional light sources and are being widely applied in various fields, such as traffic signs, backlighting modules, street lighting, and medical equipment, etc.

Referring to FIG. 1, a conventional light-emitting device 100 includes a bowl-shaped epoxy molding compound (EMC) lead frame 110, a front-mounted LED chip 120 disposed on the bowl-shaped EMC lead frame 110, and a fluorescent gel 130 encapsulating the front-mounted LED chip 120 and covering the bowl-shaped EMC lead frame 110. Due to the front-mounted LED chip 120 having a large beam angle, the fluorescent gel 130 has to fill up the bowl-shaped EMC lead frame 110 and cover the front-mounted LED chip 120, which causes yellowing of the EMC lead frame 110 due to short-wave radiation from the front-mounted LED chip 120. Moreover, the beam of light exiting the conventional light-emitting device 1 is scattered to various angles, causing problems such as glare when secondary optical processing of the conventional light-emitting device 1 is insufficient. The scattering also complicates the design for a total reflection lens to work with the conventional light-emitting device 1 if the conventional device 1 is intended to be used in backlighting a television monitor.

Referring to FIG. 2, another conventional light-emitting device 200 includes a bowl-shaped EMC lead frame 210, a vertical LED chip 220 disposed on the bowl-shaped EMC lead frame 210, a wavelength conversion layer 230 disposed only on a top light-exit region of the vertical LED chip 220, and a white glue 240 disposed on a portion of a lateral side of the vertical LED chip 220. Since the top light exit region of the LED chip 220 is lower than the opening of the bowl-shaped EMC lead frame 210, part of the light exiting the vertical LED chip 220 tends to reflect from the bowl-shaped EMC lead frame 210, which can produce glare, as shown in FIG. 3.

### SUMMARY

Therefore, an object of the disclosure is to provide a light-emitting device and an illuminating apparatus that can alleviate at least one of the drawbacks of the prior art.

According to a first aspect of the disclosure, there is provided a light-emitting device that includes a supporting component, a light-emitting diode (LED) chip, and a light-blocking layer.

The LED chip is disposed on the supporting component, and includes a substrate, a top chip surface situated above the substrate, a light-emitting semiconductor stack, a lateral side, a first electrode, and a second electrode. The substrate has a bottom end that is connected to the supporting component. The light-emitting semiconductor stack is formed between the substrate and the top chip surface to emit light toward the top chip surface. The lateral side extends downward from the top chip surface to the bottom end of the substrate.

The light-blocking layer is formed on the supporting component to surround the LED chip, and covers the lateral side of the LED chip and exposes the top chip surface.

The light-blocking layer defines a top light exit port that exposes the top chip surface and that has a cross sectional area smaller than or equal to that of the top chip surface.

According to a second aspect of the disclosure, there is provided a light-emitting device that includes a supporting component, a LED chip that has a beam angle of less than 135°, and a light-blocking layer.

The supporting component has a bottom wall and a surrounding wall that extends upwardly from the bottom wall.

The LED chip includes a substrate, a top chip surface situated above the substrate, a light-emitting semiconductor stack, a lateral side, a first electrode, and a second electrode. The substrate has a bottom end that is connected to the bottom wall. The light-emitting semiconductor stack is formed between the substrate and the top chip surface to emit light toward the top chip surface. The lateral side extends downward from the top chip surface to the bottom end of the substrate.

The light-blocking layer is formed on the bottom wall of the supporting component to surround the LED chip, and covers the lateral side of the LED chip and exposes the top chip surface. The light-blocking layer has a top surface not lower than the top chip surface.

The light-blocking layer defines a top light exit port that exposes the top chip surface and that is surrounded by the surrounding wall. The cross sectional area of the top light exit port is less than 20% of a cross section of a top end of the surrounding wall.

According to a third aspect of the disclosure, the illuminating apparatus includes the abovementioned light-emitting device.

### BRIEF DESCRIPTION OF THE DRAWINGS

Other features and advantages of the disclosure will become apparent in the following detailed description of the embodiments with reference to the accompanying drawings, of which:

FIG. 1 is a sectional view of a conventional light-emitting device;

FIG. 2 is a sectional view of another conventional light-emitting device;

FIG. 3 is a photograph of the conventional light-emitting device of FIG. 2;

FIG. 4 is a sectional view of a first embodiment of a light-emitting device according to the disclosure;

FIG. 5 is a sectional view of an LED chip of the first embodiment of the light-emitting device;

FIG. 6 is a top view of the first embodiment of the light-emitting device;

FIG. 7 is a photograph of the first embodiment of the light-emitting device;

FIG. 8 is a sectional view of a second embodiment of the light-emitting device according to the disclosure; and

FIG. 9 is a top view of the second embodiment of the light-emitting device.

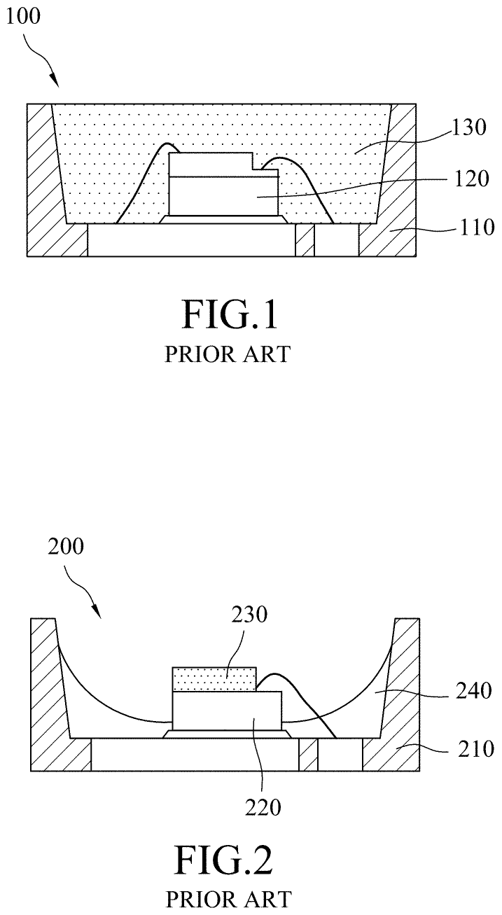

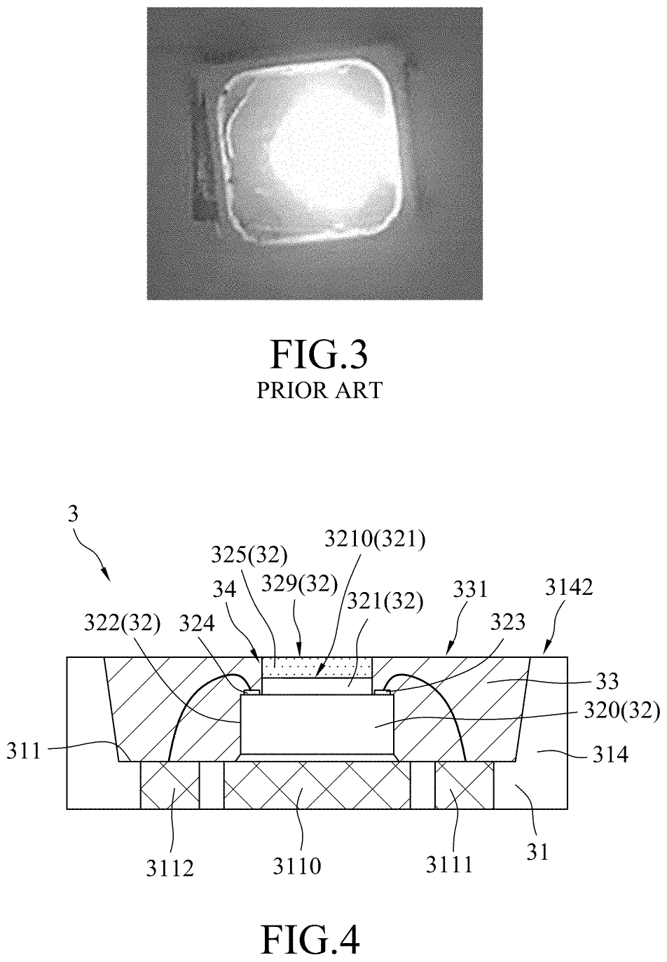

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

In addition, in the description of the present disclosure, the terms “upper”, “lower”, “upward”, “downward”, “top”, “bottom” are meant to indicate relative position between the elements of the disclosure, and are not meant to indicate the actual position of each of the elements in actual implementations.

Referring to FIG. 4, a first embodiment of a light-emitting device 3 in accordance with the present disclosure is shown. The light-emitting device 3 includes a supporting component 31, a light-emitting diode (LED) chip 32, and a light-blocking layer 33. The supporting component 31 is bowl-shaped and has a bottom wall 311 and a surrounding wall 314 that extends upwardly from the bottom wall 311. The LED chip 32 includes a substrate 320, a top chip surface 329, a light-emitting semiconductor stack 321, a lateral side 322, a first electrode 323, and a second electrode 324. The substrate 320 has a bottom end connected to the supporting component 31. The light-emitting semiconductor stack 321 is formed between the substrate 320 and the top chip surface 329 to emit light toward the top chip surface 329. The lateral side 322 extends downward from the top chip surface 329 to the bottom end of the substrate 320. The first electrode 323 is a negative electrode, and the second electrode 324 is a positive electrode. The light-blocking layer 33 is formed on the supporting component 31 to surround the LED chip 32, and covers the lateral side 322 and exposes a top surface 3210 of the light-emitting semiconductor stack 321. The light-blocking layer 33 defines a top light exit port 34 that exposes the top chip surface 329 of the LED chip 32 and that has a cross sectional area smaller than or equal to that of the top chip surface 329. In this embodiment, the light-blocking layer 33 has a top surface 331, and a height difference between the top chip surface 329 of the LED chip 32 and the top surface 331 of the light-blocking layer 33 is less than 10 μm. The bottom wall 311 supports the LED chip 32, and the surrounding wall 314 extends upwardly from the bottom wall 311 and surrounds the LED chip 32 and the light-blocking layer 33. The surrounding wall 314 has a top end 3142. A height difference among the top chip surface 329 of the LED chip 32, the top surface 331 of the light-blocking layer 33, and the top end 3142 of the surrounding wall 314 is less than 10 μm. In some embodiments, the top chip surface 329 of the LED chip 32 is flush with the top surface 331 of the light-blocking layer 33 and the top end 3142 of the surrounding wall 314.

In this embodiment, the supporting component 31 has an installation portion 3110, a first wire bonding portion 3111, and a second wire bonding portion 3112 that is electrically insulated from the first wire bonding portion 3111. The LED chip 32 is disposed on the installation portion 3110. The first electrode 24 is electrically connected to the first wire bonding portion 3111, and the second electrode is electrically connected to the second wire bonding portion 3112. The installation portion 3110 is electrically and thermally insulated from the first and second wire bonding portions 3111, 3112.

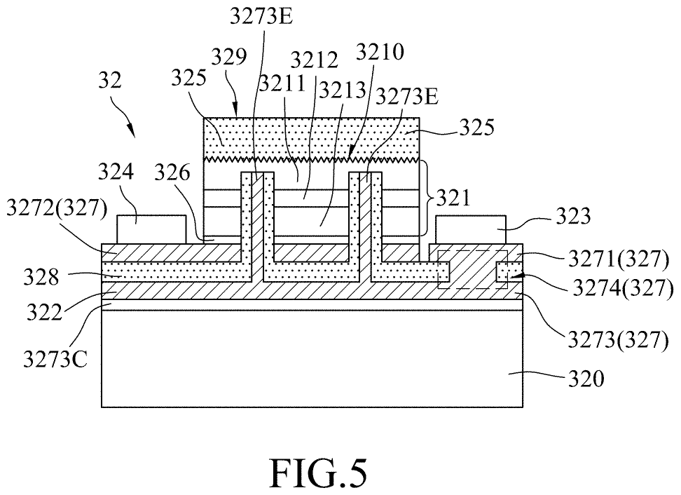

Referring to FIG. 5, the light-emitting semiconductor stack 321 of the LED chip 32 is supported by the substrate 320. In this embodiment, the light-emitting semiconductor stack 321 includes a first semiconductor layer 3211, an active layer 3212 that is disposed below the first semiconductor layer 3211, and a second semiconductor layer 3213 that is disposed below the active layer 3212. In this embodiment, the first semiconductor layer 3211 and the second semiconductor layer 3213 are an n-type semiconductor layer and a p-type semiconductor layer, respectively. The first semiconductor layer 3211 and the second semiconductor layer 3213 may be made from, for example but not limited to, a nitride material with a formula AlₓIn_{y}Ga_{(1-x-y)}N, wherein 0≤x≤1, 0≤y≤1, and 0≤x+y≤1. The first semiconductor layer 3211 and the second semiconductor layer 3213 may also be made from, for example but not limited to, a GaAs-based semiconductor material or a GaP-based AlGaInP semiconductor material. The active layer 3212 may include a nitride-based multi quantum well structure, such as InGaN/GaN, GaN/AlGaN, GaInP/AlGaInP, InGaP/GaP, GaP/AlGaP, etc., but not limited thereto.

The LED chip 32 further includes a wavelength conversion layer 325 that defines the top chip surface 329. The wavelength conversion layer 325 is disposed in the top light exit port 34 and on top of the light-emitting semiconductor stack 321. The thickness of the wavelength conversion layer 325 may range from 50 μm to 150 μm. The wavelength conversion layer 325 absorbs a first light emitted from the light-emitting semiconductor stack 321 and emits at least one second light that has a peak wavelength different from a peak wavelength of the first light emitted from the light-emitting semiconductor stack 321. In some embodiments, the active layer 3212 of the light-emitting semiconductor stack 321 emits light with a wavelength that may range from 350 nm to 445 nm. In some embodiments, the active layer 3212 of the light-emitting semiconductor stack 321 emits light with a wavelength that may range from 445 nm to 480 nm. The wavelength conversion layer 325 may be made of, but not limited to being made of, a fluorescent film, a fluorescent gel, a fluorescent ceramic material, or combinations thereof. When the wavelength conversion layer 325 is mainly a fluorescent film or a fluorescent gel, the wavelength conversion layer 325 may have a thickness ranging from 50 μm to 150 μm. When the wavelength conversion layer 325 is mainly a fluorescent ceramic material, the wavelength conversion layer 325 may have a thickness ranging from 100 μm to 300 μm. In some embodiments, the wavelength conversion layer 325 is a fluorescent film which is glued to the top surface 3210 of the light-emitting semiconductor stack 321 and has a thickness ranging from 90 μm to 120 μm so that the top surface 331 of the light-blocking layer 33 is flush with the top chip surface 329 of the LED chip 32, and the light-blocking layer 33 can cover the metal wires that connect the first and second electrodes 323, 324 to the first and second wire bonding portions 3111, 3112, respectively. The LED chip 32 according to the first embodiment of the present disclosure further includes a layered conductor unit 327, and an insulation layer 328. The layered conductor unit 327 is disposed between the substrate 320 and the light-emitting semiconductor stack 321. In this embodiment, the layered conductor unit 327 includes a first electrical connecting layer 3271, a second electrical connecting layer 3272, a third electrical connecting layer 3273, and an electrical connecting component 3274. The first electrical connecting layer 3271 is electrically connected to the first electrode 323. The second electrical connecting layer 3272 is electrically connected to the second electrode 324, and is electrically insulated from the first electrical connecting layer 3271. The third electrical connecting layer 3273 is electrically connected to the first electrical connecting layer 3271, and is electrically insulated from the second electrical connecting layer 3272. The electrical connecting component 3274 electrically connects the third electrical connecting layer 3273 and the first electrical connecting layer 3271. The insulation layer 328 separates the third electrical connecting layer 3273 from the second electrical connecting layer 3272. The third electrical connecting layer 3273 includes a plurality of extending portions 3273E that extends from the third electrical connecting layer 3273 toward the top light exit port 34, that is electrically connected to the first semiconductor layer 3211, and that is electrically insulated from the active layer 3212 and the second semiconductor layer 3213. The insulation layer 328 separates the extending portions 3273E from the active layer 3212 and the second semiconductor layer 3213. In some embodiments, the first electrical connecting layer 3271 has the same thickness as the second electrical connecting layer 3272. In some embodiments, the first electrical connecting layer 3271 is made of the same material and has the same thickness as the second electrical connecting layer 3272, and the first electrical connecting layer 3271 and the second electrical connecting layer 3272 are formed simultaneously via a patterning technique in the same processing step. This is convenient for subsequently making the first electrode 323 and the second electrode 324 to be equal in height.

In this embodiment, an interface of the first electrical connecting layer 3271 that is in contact with the first electrode 323 and an interface of the second electrical connecting layer 3272 that is in contact with the second electrode 324 may be made of a stable metal, such as Ti, Pt, Au, Cr, or TiW. The first electrical connecting layer 3271 may include a highly reflective metallic material (e.g., Ag, Al, etc.) that can reflect light emitted from the LED chip 32 while being able to prevent diffusion of the above-described stable metal (i.e., Ti, Pt, Au, Cr, or TiW). The third electrical connecting layer 3273 including the extending portion 3273E may be made from a material such as Al, Cr, Ag, or the like.

The third electrical connecting layer 3273 may include a coupling layer 3273C that is in direct contact with the substrate 320, so as to couple the third electrical connecting layer 3273 with the substrate 320. In certain embodiments, the coupling layer 3273C may be a heat-dissipating layer so that heat accumulated in the first semiconductor layer 3211 can be dissipated or transferred to the substrate 320. In some embodiments, the extending portions 3273E of the third electrical connecting layer 3273 are evenly distributed so as to improve heat dissipation and current distribution. In certain embodiments, the third electrical connecting layer 3273 has a total contact area with the first semiconductor layer 3211 that is greater than 1.5% of an area of the first semiconductor layer 3211. In other embodiments, the total contact area may range from 2.3% to 2.8%, from 2.8% to 4%, or from 4% to 6% of the area of the first semiconductor layer 3211. Increasing the total contact area between the third electrical connecting layer 3273 and the first semiconductor layer 3211 may solve heat dissipation problems in high-power devices (e.g., large size chips or high-voltage chips). However, while increasing the total contact area between the third electrical connecting layer 3273 and the first semiconductor layer 3211 can effectively increase heat dissipation capability, if the diameters of the extending portions 3273E are small, the extending portions 3273E may have an exceptionally large thermal resistance and low heat dissipation capability. Therefore, in some embodiments, each of the extending portions 3273E has a diameter of greater than 15 μm. In certain embodiments, each of the extending portions 3273E has a diameter ranging between 32 μm and 40 μm. When each of the extending portions 3273E has a diameter ranging between 34 μm and 36 μm, the number of extending portions 3273E may be 20-25. In addition, in order to lower the electrical resistance between the second electrical connecting layer 3272 and the second semiconductor layer 3213, a current extension layer 326 may be disposed therebetween. In some embodiments, the current extension layer 326 is transparent.

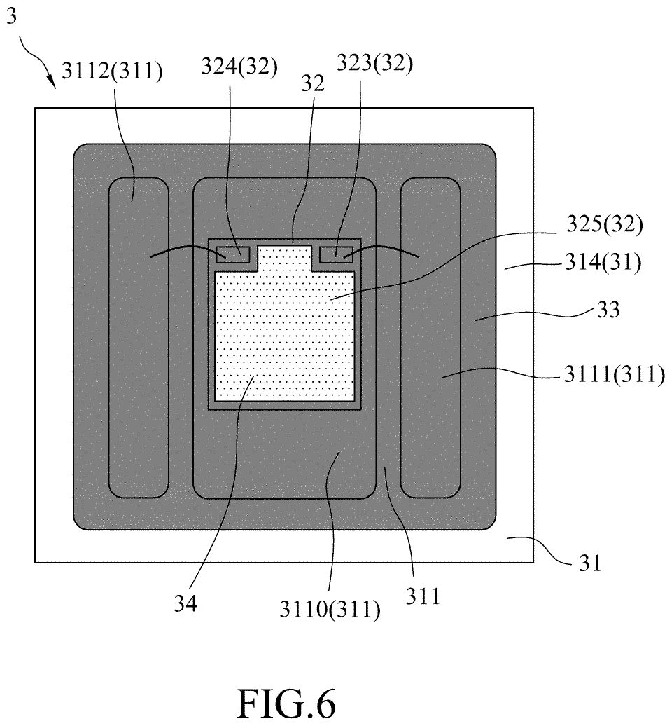

The first electrode 323 and the second electrode 324 of the LED chip 32 are located below the top chip surface 329 and disposed outside an outer lateral surface of the light-emitting semiconductor stack 321 (see FIGS. 5 and 6). The first and second electrodes 323, 324 are connected to the first, second, and third electrical connecting layers 3271, 3271, 3273 disposed at a lower side of the light-emitting semiconductor stack 321, and are positioned at an upper surface of the light-emitting semiconductor stack 321. A top surface of the first electrode 323 is at the same height as a top surface of the second electrode 324.

In this embodiment, the substrate 320 has a thickness ranging between 50 μm and 200 μm. In some embodiments, the thickness ranges between 50 μm and 100 μm, e.g., 90 μm. In some embodiments, the thickness ranges between 100 μm and 150 μm, e.g., 120 μm, or 130 μm. In some embodiments, the thickness ranges between 150 μm and 200 μm, e.g., 180 μm. In some embodiments, the substrate 320 may be, but is not limited to being, a substrate that has excellent heat-dissipating properties, such as a Si substrate, a Cu substrate, or a ceramic substrate. Since excitation radiation of the active layer 3212 is emitted from the first semiconductor layer 3211, heat tends to accumulate in the second semiconductor layer 3213. Because the layered conductor unit 327 connects the substrate 320 and the second semiconductor layer 3213, a thermal conduction path is formed to conduct heat from the second semiconductor layer 3213 to the substrate 320, thereby dissipating the heat accumulated in the second semiconductor layer 3213.

According to the first embodiment of the present disclosure, by increasing the total contact area between the third electrical connecting layer 3273 and the first semiconductor layer 3211, installing the LED chip 32 on the installation portion 3110 that is electrically and thermally insulated from the first and second wire bonding portions 3111, 3112, and respectively connecting the first and second wire bonding portions 3111, 3112 to the first and second electrodes 323, 324, the heat generated from the LED chip 32 can be transferred efficiently through the electrical connecting layer 327 and the substrate 320, and released from the installation portion 3110, which is advantageous for allowing the light-emitting device 3 to be driven by a high current density. Therefore, the light-emitting device 3 is suitable for applications using a current density of greater than 2 A/mm². In some cases, the light-emitting device 3 can be driven by a current density as high as 5 A/mm², and heat may still be efficiently dissipated by the light-emitting device 3. Therefore, the light-emitting device 3 of the present disclosure may solve the heat accumulation and heat dissipation problems posed by using a high current density to drive a light emission region with a limited area.

In this embodiment, the substrate 320 of the LED chip 32 is made of a non-transparent heat-dissipating substrate. In certain embodiments, the LED chip 32 further includes a reflecting layer (not shown) that is disposed between the light-emitting semiconductor stack 321 and the substrate 320, to reduce light-emitting areas at the lateral side 322 of the LED chip 32. In certain embodiments, the LED chip 32 has a beam angle of less than 150°. In some embodiments, the beam angle of the LED chip 32 is not greater than 135°, for example, 110° to 135°. This can ensure that light is emitted only from the top chip surface 329 of the wavelength conversion layer 325. Thus, the wavelength conversion layer 325 only needs to cover the top chip surface 329 of the light-emitting semiconductor stack 321 and not the lateral side 322 of the light-emitting semiconductor stack 321. The problems posed by the need for covering the lateral side 322 of the light-emitting semiconductor stack 321 with the wavelength conversion layer 325 can therefore be eliminated.

The light-blocking layer 33 fills the bowl-shaped supporting component 31 to cover the lateral side 322 of the LED chip 32. The top surface 331 of the light-blocking layer 33 is not lower than the top chip surface 329 of the light-emitting semiconductor stack 321, so that light emitted from the top chip surface 329 cannot be reflected from the top surface 331 of the light-blocking layer 33 or be emitted toward the surrounding wall 314 of the supporting component 31, and thus a highly focused beam of light can be obtained. The light-blocking layer 33 may be, but not limited to, an encapsulating glue having a coloring agent. The coloring agent may be of a color white or black, but not limited thereto. In some embodiments, the light-emitting device 3 can be applied to backlight illumination or projection illumination, and the light-blocking layer 33 may be a light reflecting layer, such as a light-reflecting gel (e.g., white glue), so that while obtaining a highly focused axial light, the luminous efficiency of the beam of light is not decreased. In some embodiments, the light-emitting device 3 can be applied in an RGB display, and the light-blocking layer 33 may be a light absorptive layer, such as a carbon-containing glue, so as to increase the contrast ratio of the RGB display.

Referring to FIG. 6, according to the first embodiment of the present disclosure, an axis of light emission of the LED chip 32 coincides with an axis of geometry of the light-emitting device 3. The top chip surface 329 defined by the wavelength conversion layer 325 is uncovered by the light-blocking layer 33.

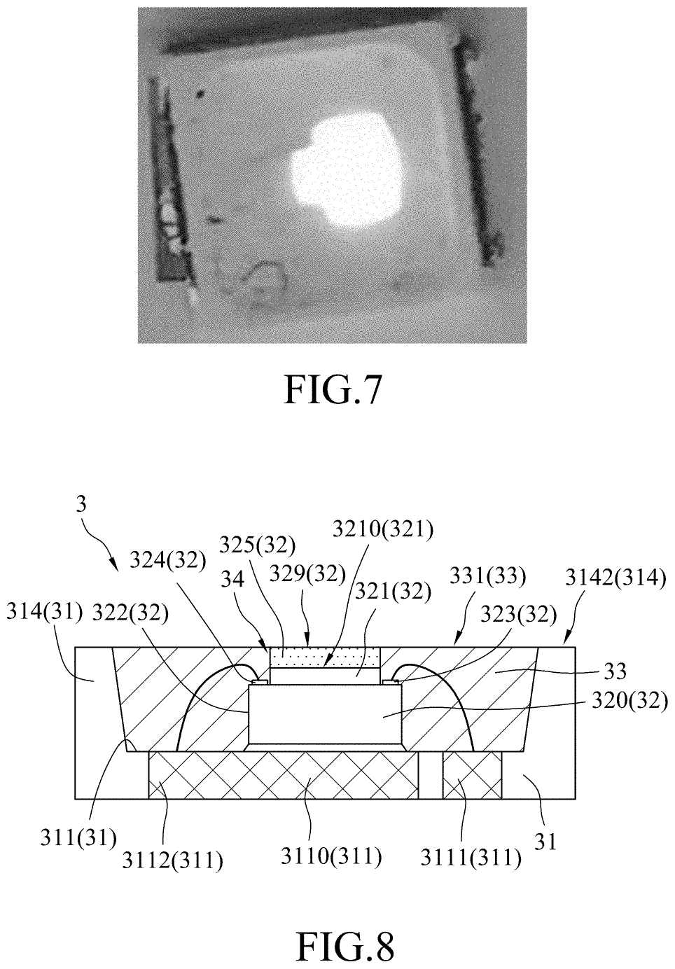

Referring to FIG. 7, the first embodiment of the light-emitting device 3 is a point light source, and the area of light emission thereof is the same as the top chip surface 329 of the LED chip 32 (see FIG. 6). In some embodiments, the top light exit port 34 of the light-blocking layer 33, or the top chip surface 329 of the LED chip 32 has an area that is less than 20% of a cross section of the top end 3142 of the surrounding wall 314. In some embodiments, the area is less than 15% of the cross section of the top end 3142 of the surrounding wall 314, so that a small facula that facilitates subsequent secondary optical processing is obtained.

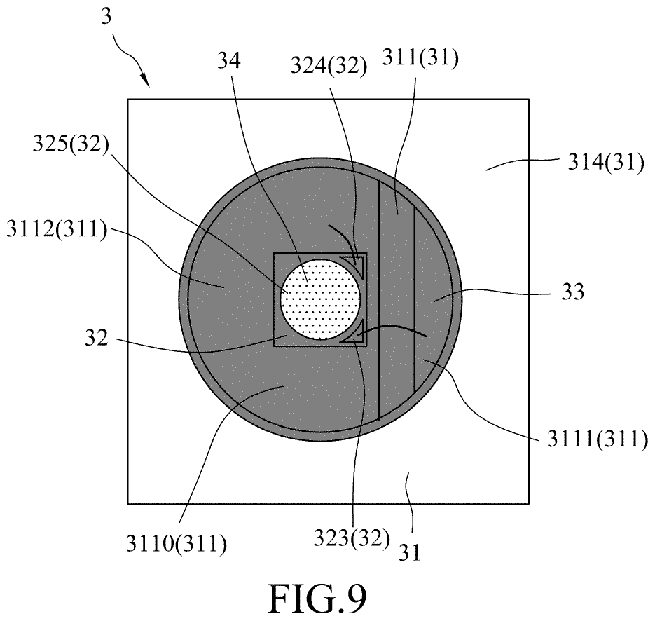

Referring to FIGS. 8 and 9, a second embodiment of the light-emitting device 3 of the present disclosure is similar to the first embodiment except that the wavelength conversion layer 325 covers only a portion of the top surface 3210 of the light-emitting semiconductor stack 321, and that the installation portion 3110 is only electrically insulated from the first wire bonding portion 3111. The shape of the wavelength conversion layer 325 may be configured to be, but not limited to being, a circular or annular shape according to optical application requirements. The light-blocking layer 33 covers a remaining portion of the top surface 3210 of the light-emitting semiconductor stack 321 not covered by the wavelength conversion layer 325 so that the top light exit port 34 has a unique shape. In this embodiment, the installation portion 3110 is not electrically insulated from the second wire bonding portion 3112, and thus, the second embodiment is suitable to be driven by a current density ranging from 2 A/mm² to 4 A/mm². When a driving current density of 4 A/mm² or above is needed, it is more suitable to use the supporting component 31 of the first embodiment of the present disclosure, which adopts a structure that has complete electro-thermal isolation.

In a variation of the second embodiment, the first electrode 323 and second electrode 324 of the LED chip 32 can be located at opposite sides of the light-emitting semiconductor stack 321. The substrate 320 is electrically conductive, and the first electrode 323 can electrically connect to a back side of the substrate 320 through the third electrical connecting layer 3273 to reduce the amount of metal wire used. In this case, the light-blocking layer 33 covers or embeds only one metal wire that connects one electrode of the LED chip 32 to one wire bonding portion. This variation reduces the amount of the metal wire used. While the wavelength conversion layer 325 is used in the embodiments described hereinabove, the wavelength conversion layer 325 may be substituted by an insulating protection layer in other embodiments. The insulating protection layer may be made of a transparent material.

The abovementioned light-emitting device 3 can be applied in an illuminating apparatus, such as a backlighting apparatus. In manufacturing a backlight apparatus using the light-emitting device 3, since the light exit port 34 of the light-emitting device 3 of the present disclosure is smaller than or equal to the top chip surface 329 of the LED chip 32, the light-emitting device 3 can be used in combination with small size lenses, whereby a light mixing distance (i.e., optical distance (OD)) can be shortened to below 15 mm. In an example of the backlighting apparatus, the OD is 10 mm.

In view of the aforementioned, the light-emitting device of the present disclosure has a small beam angle (e.g. less than 135°), which produces a strong axial light. By forming a light-blocking layer that covers the lateral side of the LED chip and that has a top surface located not lower than a top chip surface of the LED chip, the light-emitting device can have a light-emitting surface not greater than the top chip surface of the LED chip. In addition, by controlling the area of a top light exit port defined by the light-blocking layer to be smaller than or equal to 20% of a cross section of a top end of the surrounding wall of the light-emitting device, a single point light source can be obtained, which simplifies secondary optical processing. To enhance the intensity of the point light, a plurality of extending portions cooperates with the substrate and the electrical connecting layers to form a fast heat dissipation path at the back side of the LED chip opposite to the top light exit port, thus enabling high current density drive of the light-emitting device.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A light-emitting device, comprising:
a supporting component;
a light-emitting diode (LED) chip that is disposed on said supporting component, and that includes
a substrate having a bottom end connected to said supporting component,
a top chip surface that is situated above said substrate,
a light-emitting semiconductor stack formed between said substrate and said top chip surface to emit light toward said top chip surface,
a lateral side extending downward from said top chip surface to said bottom end of said substrate,
a first electrode, and
a second electrode; and
a light-blocking layer that is formed on said supporting component to surround said LED chip, and that covers said lateral side and exposes said top chip surface,
wherein said light-blocking layer defines a top light exit port that exposes said top chip surface and that has a cross sectional area smaller than or equal to that of said top chip surface.

2. The light-emitting device as claimed in claim 1, wherein said LED chip has a beam angle of not greater than 135°.

3. The light-emitting device as claimed in claim 1, wherein
said light-blocking layer has a top surface; and
a height difference between said top chip surface and said top surface of said light blocking layer is less than 10 μm.

4. The light-emitting device as claimed in claim 3, wherein:
said supporting component includes a bottom wall supporting said LED chip, and a surrounding wall extending upwardly from said bottom wall and surrounding said LED chip and said light blocking layer;
said surrounding wall has a top end; and
a height difference between said top chip surface and said top end of said surrounding wall is less than 10 μm.

5. The light-emitting device as claimed in claim 4, wherein a cross sectional area of said top light exit port is less than 20% of a cross-section of said top end of said surrounding wall.

6. The light-emitting device as claimed in claim 4, wherein said top chip surface is flush with said top end of said surrounding wall.

7. The light emitting device as claimed in claim 1, wherein
said supporting component has an installation portion, a first wire bonding portion, and a second wire bonding portion that is electrically insulated from said first wire bonding portion;
said LED chip is disposed on said installation portion;
said first electrode is electrically connected to said first wire bonding portion;
said second electrode is electrically connected to said second wire bonding portion;
said light-emitting device further comprises at least one metal wire connecting one of said first and second electrodes to one of said first and second wire bonding portions; and
said light-blocking layer covers said at least one metal wire.

8. The light-emitting device as claimed in claim 1, wherein an axis of light emission of said LED chip coincides with an axis of geometry of said light-emitting device.

9. The light-emitting device as claimed in claim 1, wherein said LED chip further includes a wavelength conversion layer disposed in said top light exit port, covering said light-emitting semiconductor stack, and defining said top chip surface, said wavelength conversion layer having a thickness ranging from 50 μm to 150 μm.

10. The light-emitting device as claimed in claim 9, wherein said wavelength conversion layer covers a portion of said light-emitting semiconductor stack, said light-blocking layer covering a remaining portion of said light-emitting semiconductor stack not covered by said wavelength conversion layer.

11. The light-emitting device as claimed in claim 1, wherein said LED chip further includes a reflecting layer that is disposed between said light-emitting semiconductor stack and said substrate.

12. The light-emitting device as claimed in claim 1, wherein each of said first electrode and said second electrode is located outside of an outer periphery of said light-emitting semiconductor stack below said top chip surface.

13. The light-emitting device as claimed in claim 1, wherein said supporting component has an installation portion to install said LED chip and said first and second wire bonding portions to connect respectively said first and second electrodes, said installation portion is electrically and thermally insulated from said first and second wire bonding portions.

14. The light-emitting device as claimed in claim 1, wherein said light-blocking layer is a light reflecting layer or a light absorptive layer.

15. The light-emitting device as claimed in claim 1, wherein said top surface of said light-blocking layer is not lower than said top chip surface.

16. The light-emitting device as claimed in claim 1, wherein said light-emitting device is driven by a current density of greater than 2 A/mm².

17. A light-emitting device, comprising:
a supporting component having a bottom wall and a surrounding wall extending upwardly from said bottom wall;
a light-emitting diode (LED) chip that has a beam angle of less than than 135°, and that includes
a substrate having a bottom end connected to said bottom wall,
a top chip surface situated above said substrate,
a light-emitting semiconductor stack that is formed between said substrate and said top chip surface to emit light toward said top chip surface,
a lateral side extending downward from said top chip surface to said bottom end of said substrate,
a first electrode, and
a second electrode; and
a light-blocking layer that is formed on said bottom wall to surround said LED chip, and that covers said lateral side and exposes said top chip surface, said light-blocking layer having a top surface not lower than said top chip surface,
wherein said light-blocking layer defines a top light exit port that exposes said top chip surface and that is surrounded by said surrounding wall, a cross sectional area of said top light exit port being less than 20% of a cross section of a top end of said surrounding wall.

18. The light-emitting device as claimed in claim 17, wherein said LED chip further includes a reflecting layer that is disposed between said light-emitting semiconductor stack and said substrate.

19. An illuminating apparatus comprising a light-emitting device as claimed in claim 1.

20. The illuminating apparatus as claimed in claim 19, which is used for backlighting a display and which has a light mixing distance of below 15 mm.
